(19) United States
(12) Patent Application Publication
(10) Pub. No.: US 2009/0212380 A1
(43) Pub. Date: Aug. 27, 2009

(54) METHOD FOR MANUFACTURING SOLID-STATE IMAGING DEVICE

(75) Inventor: Toshiya HISASAKA, Iwate-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 12/390,610

(22) Filed: Feb. 23, 2009

(30) Foreign Application Priority Data
Feb. 25, 2008 (JP) 2008-043144

(51) Int. Cl. H01L 31/0232; H01L 31/18

(52) U.S. Cl. 257/432; 438/70; 257/E31.127; 257/E21.211

(57) ABSTRACT

A method for manufacturing a solid-state imaging device is provided.

The method includes the steps of forming a base layer 16 on a semiconductor substrate 11 with a plurality of photodiodes 12 arranged therein, forming a blue filter 17-1, a green filter 17-2 or a red filter 17-3 on the base layer 16 at a position above each of the photodiodes 12, applying a black resist layer 18a entirely so as to cover these filters 17-1, 17-2 and 17-3 and to fill in spaces between the filters 17-1, 17-2 and 17-3; and forming a black filter 18 by etching the black resist layer 18a until the upper parts of the filters 17-1, 17-2 and 17-3 are exposed.

### CROSS-REFERENCE TO RELATED APPLICATIONS

This application is based upon and claims the benefit of priority from the prior Japanese Patent Application No.2008-043144, filed on Feb. 25, 2008; the entire contents of which are incorporated herein by reference.

### TECHNICAL FIELD

The present invention relates to a method for manufacturing a solid-state imaging device, and particularly, to a method for manufacturing a filter formed between pixels of the solid-state imaging device for blocking visible light.

### BACKGROUND ART

In a conventional solid-state imaging device, a plurality of photodiodes is formed on a semiconductor substrate in a two-dimensional array. On each of the photodiodes, any one of a blue filter for allowing blue light to pass through, a green filter for allowing green light to pass through and a red filter for allowing red light to pass through is formed. In addition, on each of these filters, a micro lens for collecting light incident from outside. The photodiode, filter and micro lens are formed into a stacked structure to form a pixel. In the solid-state imaging device where a plurality of such pixels are formed, a black filter for blocking visible light is formed each space between color filters. This black filter prevents reception of light incident on the photodiodes from outside the pixel areas due to irregular reflection of incident light by wiring metal formed between the semiconductor substrate and the filter layer or due to oblique incidence of light on the pixels.

As conventional methods of manufacturing a black filter, the following two methods are known. The first method is a method of forming a transparent resin layer between pixels by patterning and dying this transparent resin layer with black pigment (see Japanese Patent Application Laid-open No. 6-125071). The second method is a method of stacking a red filter, a blue filter and a green filter between pixels (see Japanese Patent Application Laid-open No. 2000-329928). However, according to the first method, it is only after chromium is added to transparent resin thereby to give the transparent resin photosensitivity that the transparent resin layer can be formed between pixels by patterning. The chromium used in this method is an environmental pollutant and hence, this method is not preferable. In addition, the running cost for the dying process with black pigment is generally high, and therefore, this method is not much used currently.

Specifically, the second method is as follows. First, a green filter layer is applied by spin coating to the entire surface of the semiconductor substrate where a plurality of photodiodes is formed in a two-dimensional array. Then, the green filter layer is removed in a manner that a part of the green filter positioned above each photodiode which receives green light is remained and the rest part of the green filter layer is all removed. As a result, a green filter is formed. Next, likewise, a red filter and a blue filter are formed above the respective photodiodes. As a result, green, red and blue filters are stacked in areas between the photodiodes on the semiconductor substrate. As these staked filters block the visible light, they serve as a black filter.

However, according to this method, when spin coating is applied to the non-flat surface of the semiconductor substrate, a filter layer formed to be thinner on a convex portion and thicker on a concave portion, and coating becomes uneven. Therefore, it is difficult to form a filter layer of uniform thickness over the non-flat surface of the semiconductor substrate. If another filter layer is stacked on such a roughly-coated filter layer, the filter layer subsequently stacked is subjected to significantly uneven coating. For this reason, the thickness of an upper filter may greatly vary over the filter layer, and there arises a problem that the transmission characteristics of the filters vary.

### DISCLOSURE OF THE INVENTION

It is one of the objects of the present invention to provide a method for manufacturing a solid-state imaging device capable of forming filters of uniform thickness.

A method for manufacturing a solid-state imaging device according to the present invention includes steps of forming a base layer on a semiconductor substrate with a plurality of photodiodes arranged therein; forming filters on the base layer at positions above the respective photodiodes, each of the filters transmitting light in wavelength band of any one of a plurality of colors; applying a black resist layer to an entire surface of the base layer with the filters formed thereon in such a manner as to cover the filters; and flattening the surface of the base layer with the black resist layer applied thereon by etching until surfaces of the filters are exposed.

A method for manufacturing a solid-state imaging device according to another aspect of the present invention comprises the steps of: forming a multi-layer wiring layer on a semiconductor substrate with a plurality of photodiodes arranged therein; forming on the multi-layer wiring layer a base layer with recess portions formed above the respective photodiodes; forming filters in the respective recess portions of the base layer, each of the filters transmitting light in wavelength band of any one of a plurality of colors; applying a black resist layer to an entire surface of the base layer with the filters formed thereon in such a manner as to cover the filters; and flattening the surface of the base layer with the black resist layer applied thereon by etching until surfaces of the filters are exposed.

### BRIEF DESCRIPTION OF THE DRAWINGS

FIG. 1 is a top view of a solid-state imaging device according to first and second embodiments;

FIG. 2A is a cross sectional view taken along a broken line A-A′ of FIG. 1;

FIG. 2B is a cross sectional view taken along a broken line B-B′ of FIG. 1;

FIG. 3A is a cross sectional view taken along the broken line A-A′ of FIG. 1, for explaining the method for manufacturing the solid-state imaging device according to the first embodiment;

FIG. 3B is a cross sectional view taken along the broken line B-B′ of FIG. 1, for explaining the method for manufacturing the solid-state imaging device according to the first embodiment;

FIG. 4A is a cross sectional view taken along the broken line A-A′ of FIG. 1, for explaining the method for manufacturing the solid-state imaging device according to the first embodiment;

FIG. 4B is a cross sectional view taken along the broken line B-B′ of FIG. 1, for explaining the method for manufacturing the solid-state imaging device according to the first embodiment;

FIG. 5A is a cross sectional view taken along the broken line A-A′ of FIG. 1, for explaining the method for manufacturing the solid-state imaging device according to the first embodiment;

FIG. 5B is a cross sectional view taken along the broken line B-B′ of FIG. 1, for explaining the method for manufacturing the solid-state imaging device according to the first embodiment;

FIG. 6A is a cross sectional view taken along the broken line A-A′ of FIG. 1, for explaining the method for manufacturing the solid-state imaging device according to the first embodiment;

FIG. 6B is a cross sectional view taken along the broken line B-B′ of FIG. 1, for explaining the method for manufacturing the solid-state imaging device according to the first embodiment;

FIG. 7A is a cross sectional view taken along the broken line A-A′ of FIG. 1, for explaining the method for manufacturing the solid-state imaging device according to the first embodiment;

FIG. 7B is a cross sectional view taken along the broken line B-B′ of FIG. 1, for explaining the method for manufacturing the solid-state imaging device according to the first embodiment;

FIG. 8A is a cross sectional view taken along the broken line A-A′ of FIG. 1, for explaining the method for manufacturing the solid-state imaging device according to a second embodiment;

FIG. 8B is a cross sectional view taken along the broken line B-B′ of FIG. 1, for explaining the method for manufacturing the solid-state imaging device according to the second embodiment;

FIG. 9A is a cross sectional view taken along the broken line A-A′ of FIG. 1, for explaining the method for manufacturing the solid-state imaging device according to the second embodiment;

FIG. 9B is a cross sectional view taken along the broken line B-B′ of FIG. 1, for explaining the method for manufacturing the solid-state imaging device according to the second embodiment;

FIG. 10A is a cross sectional view taken along the broken line A-A′ of FIG. 1, for explaining the method for manufacturing the solid-state imaging device according to the second embodiment; and

FIG. 10B is a cross sectional view taken along the broken line B-B′ of FIG. 1, for explaining the method for manufacturing the solid-state imaging device according to the second embodiment.

### DETAILED DESCRIPTION OF THE INVENTION

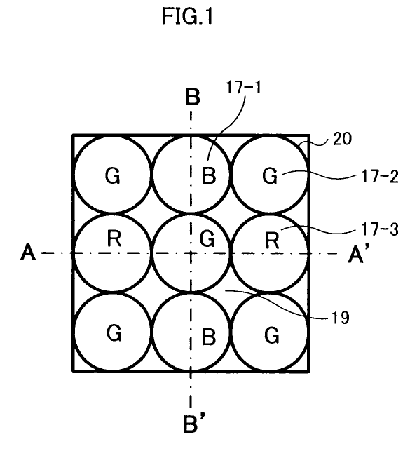

With reference to FIGS. 1 to 10, a solid-state imaging device according to embodiments of the present invention will be described in detail below.

### (FIRST EMBODIMENT)

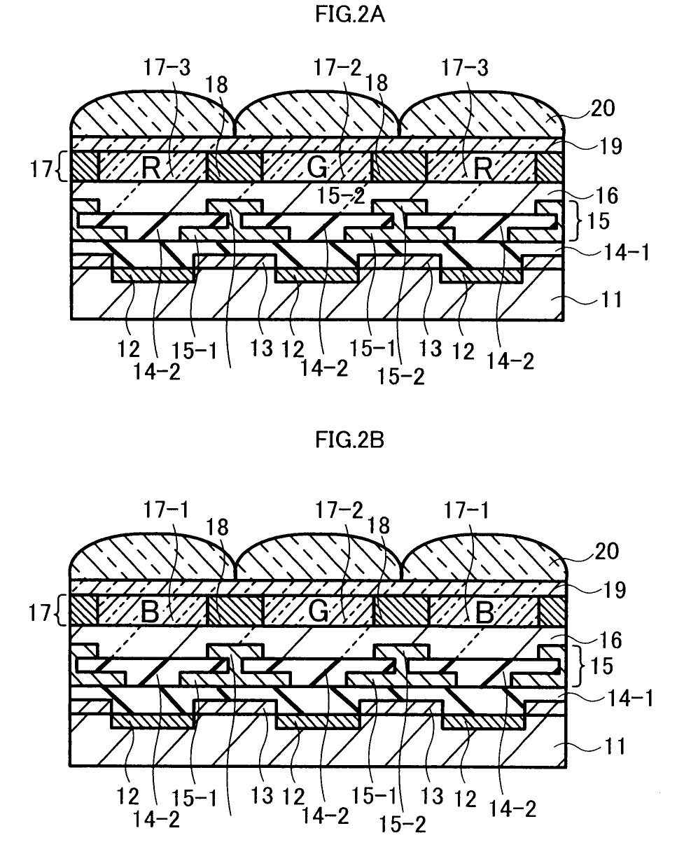

FIG. 1 is a top view of a solid-state imaging device according to the first embodiment of the present invention. FIG. 2A is a cross sectional view taken along the broken line A-A′ shown in FIG. 1, and FIG. 2B is a cross sectional view taken along the broken line B-B′ shown in FIG. 1.

As shown in FIGS. 2A and 2B, in the solid-state imaging device according to this embodiment, photodiodes 12 are embedded in a semiconductor substrate 11 to form a two-dimensional array. On the semiconductor substrate 11 with the plurality of photodiodes 12 formed therein, a transfer electrode 13 is formed in each space between the photodiodes 12. On the semiconductor substrate 11 with the transfer electrodes 13 formed thereon, a first insulating layer 14-1 is formed. On the first insulating layer 14-1, a wiring layer 15 is formed. This wiring layer 15 has a two-layer wiring structure including first wiring layers 15-1 and second wiring layers 15-2 formed on the first wiring layers 15-1 with second insulating layers 14-2 therebetween and electrically connected to the first wiring layers 15-1. On such a wiring layer 13, a base layer 16 is formed to have a flat surface. On the base layer 16, a filter layer 17 is formed. This filter layer 17 includes blue filters 17-1, green filters 17-2, and red filters 17-3, which are all formed above the respective photodiodes 12, and black filters 18 formed in spaces between the blue filters 17-1, green filters 17-2, and red filters 17-3. In this embodiment, the blue filters 17-1, green filters 17-2, and red filters 17-3 are formed in Bayer arrangement. On such a filter layer 17, an overcoat layer 19 is formed, on which micro lenses 20 are formed at positions corresponding to the respective photodiodes 12.

In such a solid-state imaging device, light passes through a micro lens 20 and a corresponding one of blue filters 17-1, green filters 17-2, and red filters 17-3 and is collected into the photodiode 12. The collected light is converted into number of electrons proportional to an amount of incident light at the photodiode 12. Then, when a voltage is applied to the transfer electrodes 13, these electrons are transferred to a desired part such as a vertical transfer resister or the like.

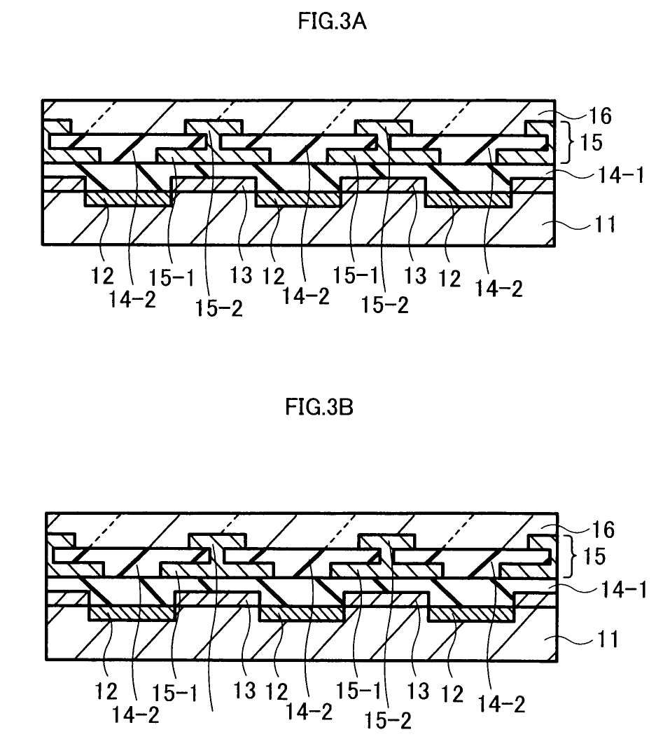

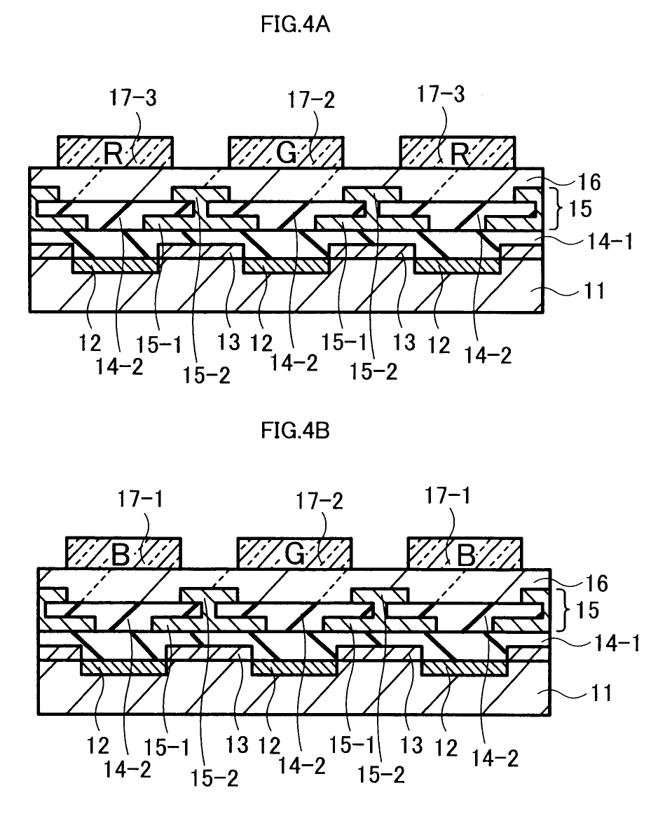

Next description is made about a method for manufacturing of the solid-state imaging device according to the present embodiment, with reference to FIGS. 3 to 7. Here, FIG. 3A is a cross sectional view taken along the broken line A-A′ of FIG. 1, for explaining the method for manufacturing the solid-state imaging device according to the first embodiment. FIG. 3B is a cross sectional view taken along the broken line B-B′ of FIG. 1, for explaining the method for manufacturing the solid-state imaging device according to the first embodiment. FIGS. 4 to 7 are similarly presented.

First, as shown in FIGS. 3A and 3B, on the semiconductor substrate 11 in which the photodiodes 12 are embedded and on which the transfer electrodes are formed, the wiring layer 15 is formed with the first insulating layer 14-1 interposed therebetween. Further, on this wiring layer 15, the base layer 16 is formed to have a flat surface.

Then, as shown in FIGS. 4A and 4B, on the base layer 16, green filters 17-2, red filters 17-3 and blue filters 17-1 are formed in this order into Bayer arrangement. These filters 17-1, 17-2 and 17-3 are formed by spin-coating color resists on the base layer 16 and performing patterning thereafter.

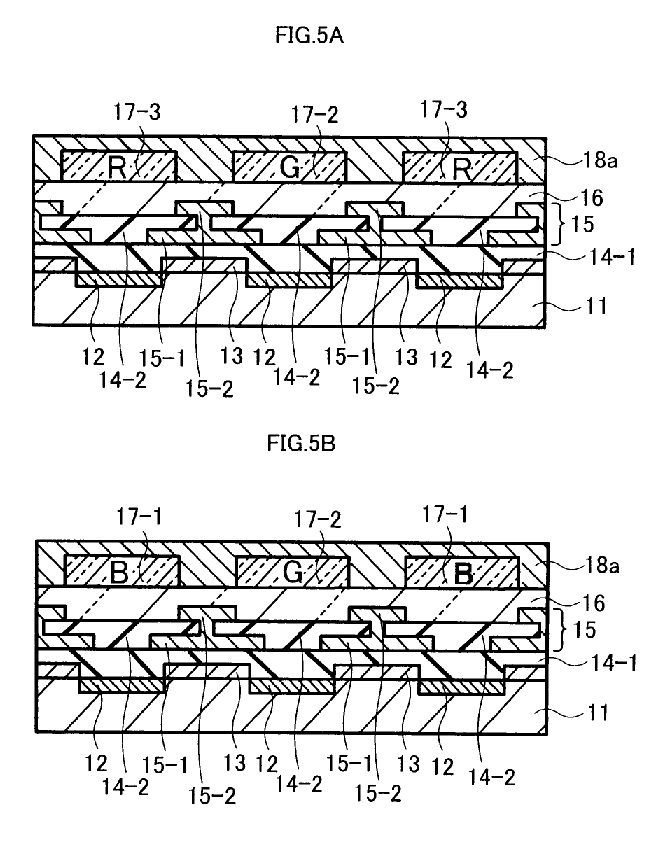

Next, as shown in FIGS. 5A and 5B, a black resist layer 18a is applied by spin coating to the entire surface over the filters 17-1, 17-2 and 17-3 and filling in the spaces between the filters. The black resist layer 18a applied at this time is of low viscosity, which makes the surface of the black resist layer 18a flat.

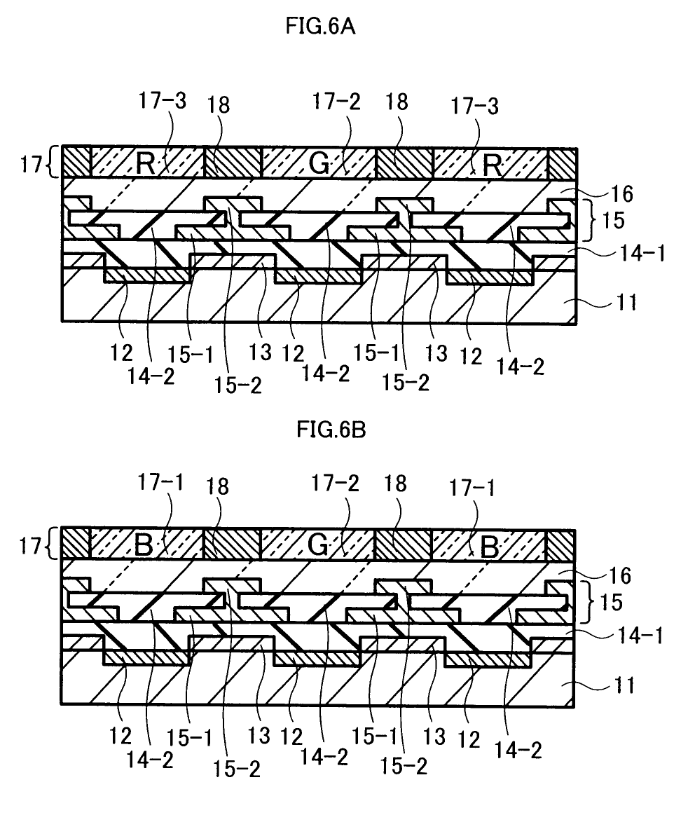

Then, as shown in FIGS. 6A and 6B, the top surface of the black resist layer 18a is etched back until the top of each of the filters 17-1, 17-2 and 17-3 is exposed. As a result of this etching back, the black filters 18 are formed in the spaces between the filters 17-1, 17-2 and 17-3, and the surface of the filter layer 17 formed of the black filters 18 and the filters 17-1, 17-2 and 17-3 is flattened.

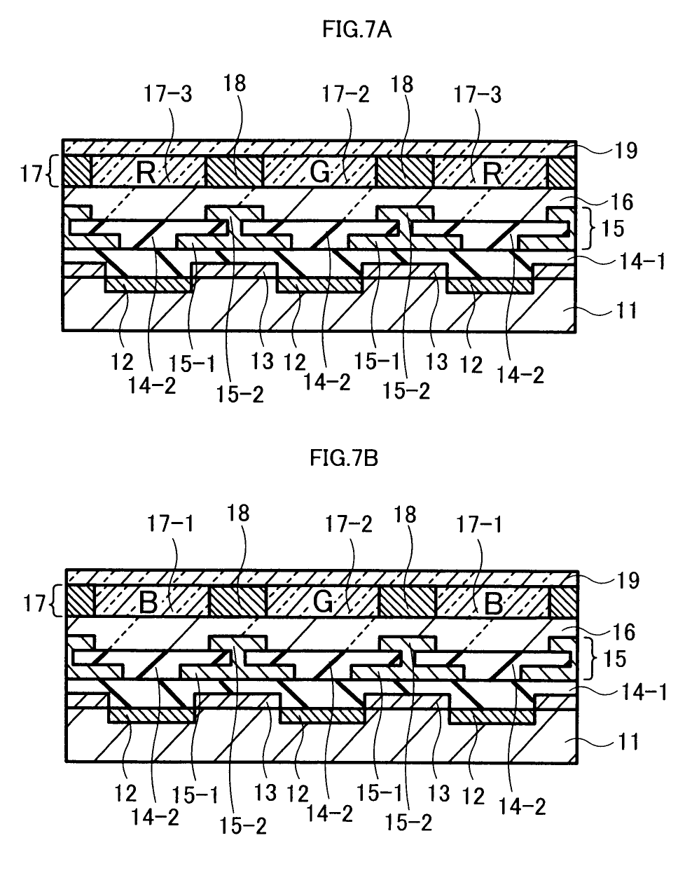

Then, as shown in FIGS. 7A and 7B, on the filter layer 17, the overcoat layer 19 is formed as a transparent layer. This overcoat layer 19 is a layer serving as a flattening layer, but, as shown in FIGS. 6A and 6B, the surface of the filter layer 17 is already flattened and there is no need to make the overcoat layer 19 thick as in the conventional method.

Finally, the micro lenses 20 are formed on the overcoat layer 19 at positions corresponding to the respective photodiodes 12.

By the manufacturing processes described above, a solid-state imaging device according to the present embodiment as shown in FIGS. 1, 2A and 2B can be manufactured.

With the method for manufacturing a solid-state imaging device according to this embodiment, a black resist layer 18a is applied to the base layer 16 so as to cover the filters 17-1, 17-2 and 17-3. Then, the black resist layer 18a is etched back until the filters 17-1, 17-2 and 17-3 are exposed on the top to form the black filters 18 between the filters 17-1, 17-2 and 17-3. Hence, a solid-state imaging device having a filter layer 17 with a substantially flat surface can be formed even the black filters 18 are formed therein.

In addition, as the surface of the filter layer 17 is already flattened before the overcoat layer 19 is formed, there is no need to thicken the overcoat layer 19, which is required in the conventional method, and thereby thinner imaging devices can be realized compared with those manufactured by the conventional method.

Further, according to this embodiment, it is possible to form a black filter which is more excellent in light blocking effect than a conventional black filter formed by making the transparent resin layer to contain black pigment. This is because the black resist layer 18a has a better light blocking effect than the black filter formed by making the transparent resin layer to contain black pigment.

### (SECOND EMBODIMENT)

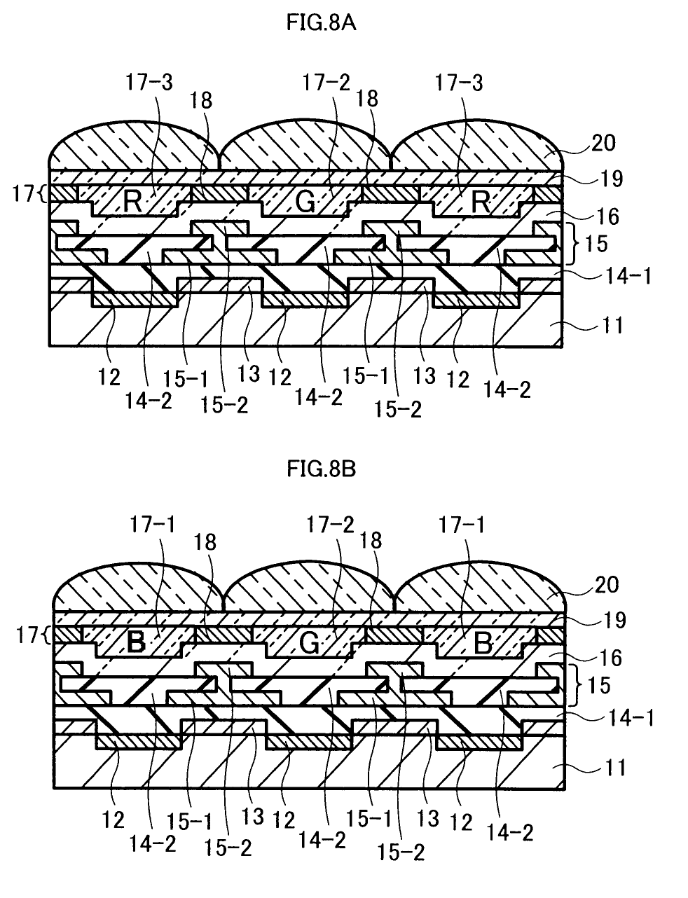

The top view of a solid-state imaging device according to the second embodiment of the present invention is shown in the same manner as that of the first embodiment. FIG. 8A is a cross sectional view taken along the broken line A-A′ of FIG. 1 and FIG. 8B is a cross sectional view taken along the broken line B-B′ of FIG. 1.

As shown in FIGS. 8A and 8B, the solid-state imaging device according to this embodiment is characterized in that a base layer 16 formed on the wiring layer 15 is not flattened and the other structures are identical to those in the first embodiment.

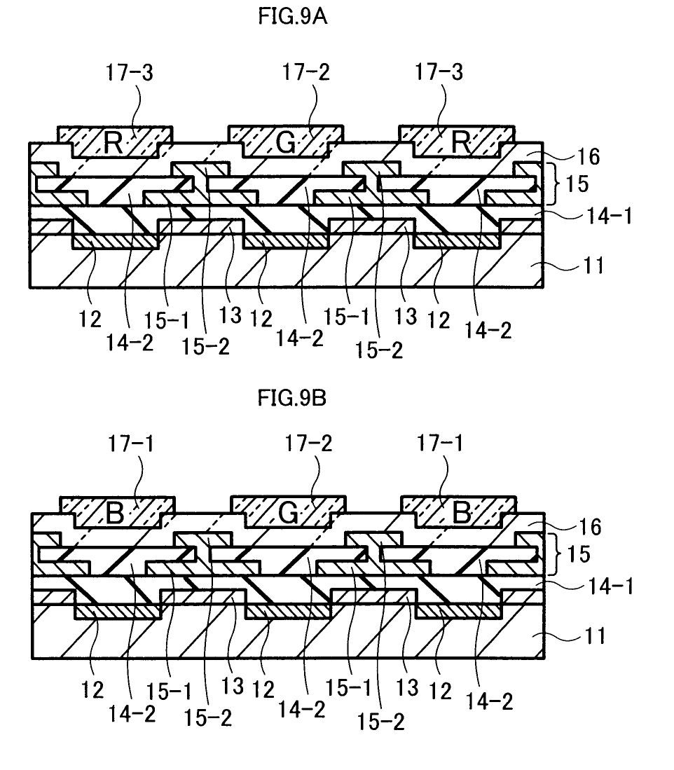

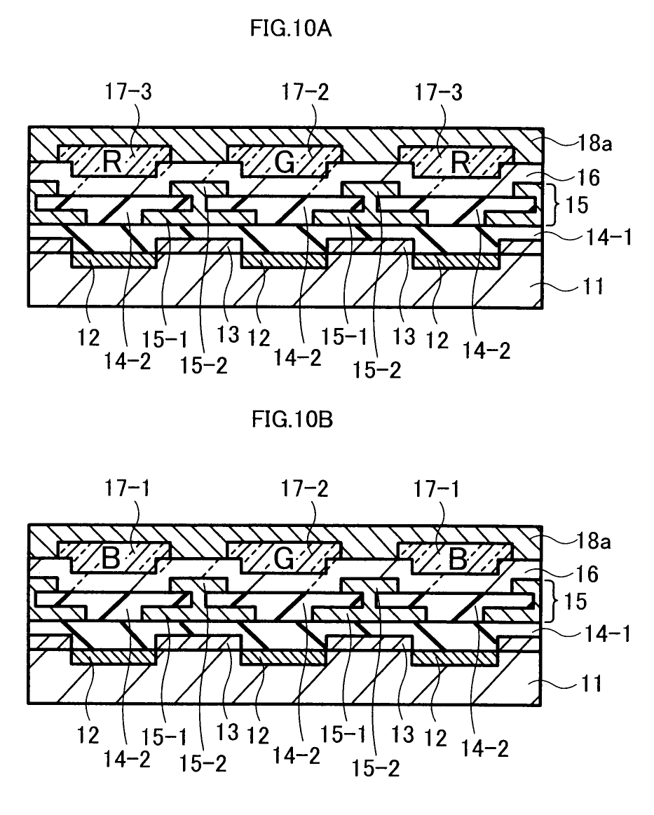

A method for manufacturing such a solid-state imaging device according to the second embodiment is described with reference to FIGS. 9 and 10. Here, FIGS. 9A and 9B are views for explaining the process of forming filters 17-1, 17-2 and 17-3 on recess portions of the base layer 16 in the method for manufacturing the solid-state imaging device according to the second embodiment. FIG. 9A is a cross sectional view taken along the broken line A-A′ of FIG. 1 and FIG. 9B is a cross sectional view taken along the broken line B-B′ of FIG. 1. FIGS. 10A and 10B are views for explaining the process of applying the black resist layer 18a onto the base layer 16 on which the filters 17-1, 17-2 and 17-3 are formed in the method for manufacturing the solid-state imaging device according to the second embodiment. FIG. 10A is a cross sectional view taken along the broken line A-A′ of FIG. 1 and FIG. 10B is a cross sectional view taken along the broken line B-B′ of FIG. 1.

First, as shown in FIGS. 9A and 9B, the base layer 16 is formed of such a thickness that recess portions are formed above the photodiodes 12, and in the recess portions of the base layer 16, green filters 17-2, red filters 17-3 and blue filters 17-1 are formed in this order into Bayer arrangement.

Then, as shown in FIGS. 10A and 10B, the black resist layer 18a is applied so as to coat the filters 17-1, 17-2 and 17-3 formed in the recess portions of the base layer 16 and fill in the spaces between the filters 17-1, 17-2 and 17-3.

The subsequent processes are the same as those in the first embodiment.

In this way, according to the method for manufacturing a solid-state imaging device according to the second embodiment, a solid-state imaging device having a filter layer 17 with a substantially flat surface can be formed similarly to the first embodiment. In addition, it is possible to realize thinner pixels than conventional ones. Further, it is possible to form a black filter of higher light blocking effect than a conventional one.

In the second embodiment, the base layer 16 is formed to be thin to such a degree that the base layer 16 is not flattened. Therefore, it is possible to achieve thinner pixels as compared to the first embodiment.

The embodiments of the present invention have been described above. However, the present invention is not limited to these embodiments.

For example, the order of manufacturing the color filters 17-1, 17-2 and 17-3 is not limited to the above-described order and may be any order. In addition, the filters formed above the photodiodes 12 are not limited to those of green, red and blue and maybe complementary color filters of, for example, Ye (yellow), Cy (cyan) , Mg (magenta) , Gr (green) and the like.

Further the wiring layer 13 is not limited to two-layer wiring structure and may be a wiring structure of any number of layers.

Furthermore, the solid-state imaging device of the present invention is not limited to a solid-state imaging device structured to have filters formed in Bayer arrangement, but the present invention may also be applied to a solid-state imaging device, which is structured to have filters arranged differently, in which micro lenses are not used, a linear sensor and the like.

1. A method for manufacturing a solid-state imaging device comprising steps of:
forming a base layer on a semiconductor substrate with a plurality of photodiodes arranged therein;
forming filters on the base layer at positions above the respective photodiodes, each of the filters transmitting light in wavelength band of any one of a plurality of colors;
applying a black resist layer to an entire surface of the base layer with the filters formed thereon in such a manner as to cover the filters; and
flattening the surface of the base layer with the black resist layer applied thereon by etching until surfaces of the filters are exposed.

2. The method for manufacturing a solid-state imaging device according to claim 1, wherein the step of flattening includes a step of flattening the surface of the base layer by etching back until the surfaces of the filters are exposed.

3. The method for manufacturing a solid-state imaging device according to claim 1, wherein the step of forming filters includes a step of forming a blue filter, a red filter and a green filter sequentially.

4. The method for manufacturing a solid-state imaging device according to claim 3, wherein the blue filter, the red filter and the green filter are formed into Bayer arrangement.

5. The method for manufacturing a solid-state imaging device according to claim 3, wherein an overcoat layer having a flat surface is formed on the black filter, the blue filter, the red filter, and the green filter, which are formed by flattening the surface of the black resist layer.

6. The method for manufacturing a solid-state imaging device according to claim 5, wherein a micro lens is formed on the overcoat layer at a position corresponding to each of the photodiodes.

7. A method for manufacturing a solid-state imaging device comprising the steps of:
forming a multi-layer wiring layer on a semiconductor substrate with a plurality of photodiodes arranged therein;
forming on the multi-layer wiring layer a base layer with recess portions formed above the respective photodiodes;
forming filters in the respective recess portions of the base layer, each of the filters transmitting light in wavelength band of any one of a plurality of colors;
applying a black resist layer to an entire surface of the base layer with the filters formed thereon in such a manner as to cover the filters; and
flattening the surface of the base layer with the black resist layer applied thereon by etching until surfaces of the filters are exposed.

8. The method for manufacturing a solid-state imaging device according to claim 7, wherein the step of flattening includes a step of flattening the surface of the base layer by etching back until the surfaces of the filters are exposed.

9. The method for manufacturing a solid-state imaging device according to claim 7, wherein the step of forming filters includes a step of forming a blue filter, a red filter and a green filter sequentially.

10. The method for manufacturing a solid-state imaging device according to claim 9, wherein the step of forming filters includes a step of forming the blue filter, the red filter and the green filter into Bayer arrangement.

11. The method for manufacturing a solid-state imaging device according to claim 9, wherein an overcoat layer having a flat surface is formed on the black filter, the blue filter, the red filter and the green filter, which are formed by flattening the surface of.

12. The method for manufacturing a solid-state imaging device according to claim 11, wherein a micro lens is formed on the overcoat layer at a position corresponding to each of the photodiodes.

13. An imaging device comprising:
a base layer formed on a semiconductor substrate with a plurality of photodiodes arranged therein;
filters formed on the base layer at positions above the respective photodiodes, each of the filters transmitting light in wavelength band of any one of a plurality of colors;
a black resist layer applied to spaces between any two of the filters so that a surface formed by the black resist layer and the filters may be substantially flat.

14. The imaging device according to claim 13, wherein the filters are a red filter, a blue filter and a green filter.

15. The imaging device according to claim 14, wherein the red filter, the blue filter and the green filter are formed into Bayer arrangement.

16. The imaging device according to claim 13, wherein an overcoat layer is formed on the filters.

17. The imaging device according to claim 16, wherein a micro lens is formed on the overcoat layer at a position corresponding to each of the photodiodes.
